(19) United States
(12) Patent Application Publication
(10) Pub. No.: US 2017/0098420 A1
(43) Pub. Date: Apr. 6, 2017

(54) SCAN DRIVER AND DRIVING METHOD THEREOF

(71) Applicant: SAMSUNG DISPLAY CO., LTD., Yongin-city (KR)

(72) Inventors: Sun Koo KANG, Yongin-si (KR); Tae Gon KIM, Yongin-si (KR); Kyung Ha KIM, Yongin-si (KR); Jae Han LEE, Yongin-si (KR)

(21) Appl. No.: 15/132,547

(22) Filed: Apr. 19, 2016

(30) Foreign Application Priority Data
Oct. 1, 2015 (KR) 10-2015-0138690

(51) Int. Cl. G09G 3/36; H03K 17/687; H03K 5/06; H03K 3/356

(52) U.S. Cl. CPC G09G 3/3677; G09G 3/3688; H03K 3/356; H03K 17/6871; H03K 5/06; G09G 2300/0809; G09G 2310/0291; G09G 2320/0223; G09G 2320/0219

(57) ABSTRACT

A scan driver includes stages respectively located in channels, the stages outputting a sampling signal, corresponding to at least one clock signal, and a buffer unit including buffers respectively located between the stages and scan lines, the buffers each outputting a scan signal to an output terminal thereof, corresponding to the sampling signal supplied through an input terminal thereof where an ith (i is a natural number) buffer located in an ith channel is electrically coupled to at least one specific buffer located in another channel different from the ith channel.

This application claims priority to Korean Patent Application No. 10-2015-0138690, filed on Oct. 1, 2015, and all the benefits accruing therefrom under 35 U.S.C. §119, the content of which in its entirety is herein incorporated by reference.

### BACKGROUND

1. Field

Exemplary embodiments of the invention relate to a scan driver and a driving method thereof, and more particularly, to a scan driver and a driving method thereof, which may improve a slew rate.

2. Description of the Related Art

With a development of information technologies, an importance of a display device which is a connection medium between a user and information increases. Accordingly, display devices such as a liquid crystal display device and an organic light emitting display device are increasingly used.

In general, a display device includes a data driver for supplying data signals to data lines, a scan driver for supplying scan signals to scan lines, and a pixel unit including pixels arranged in areas defined by the scan lines and the data lines.

Pixels included in the pixel unit are selected when a scan signal is supplied to a scan line, thereby receiving a data signal supplied from a data line. The pixels supplied with the data signal transmit light of a luminance corresponding to the data signal to the outside.

The scan driver includes stages for generating a sampling signal and buffers located between the stages and the scan lines. The buffers generate a scan signal using the sampling signal, and output a gate-on voltage (i.e., a scan signal) during a period in which a sampling signal is supplied, and outputs a gate-off voltage during the other period.

As panels become large-sized, an RC delay of scan lines is increased, and accordingly, a slew rate is lowered. Thus, there has been proposed a technique for mounting a plurality of buffers in each channel so as to improve the slew rate of a scan driver.

### SUMMARY

When a plurality of buffers is mounted in each channel of the scan driver, a mounting area and a manufacturing cost of a scan driver are increased. Accordingly, a method for improving a slew rate while minimizing the mounting area of the scan driver is desired.

Exemplary embodiments provide a scan driver and a driving method thereof, which may improve a slew rate.

According to an exemplary embodiment of the invention, there is provided a scan driver including stages respectively located in channels, the stages outputting a sampling signal, corresponding to at least one clock signal, and a buffer unit including buffers respectively located between the stages and scan lines, the buffers each outputting a scan signal to an output terminal thereof, corresponding to the sampling signal supplied through an input terminal thereof, wherein an ith (i is a natural number) buffer located in an ith channel is electrically coupled to at least one specific buffer located in another channel different from the ith channel.

In an exemplary embodiment, an input terminal of the ith buffer may be electrically coupled to an input terminal of the specific buffer, and an output terminal of the ith buffer may be electrically coupled to an output terminal of the specific buffer.

In an exemplary embodiment, the scan driver may further include first switches respectively coupled between the buffers and the scan lines.

In an exemplary embodiment, a first switch coupled to the ith buffer may be turned off when the sampling signal is supplied to the specific buffer, and otherwise, set to a turn-on state.

In an exemplary embodiment, the scan driver may further include a second switch coupled between the input terminal of the ith buffer and the input terminal of the specific buffer, and a third switch coupled between the output terminal of the ith buffer and the output terminal of the specific buffer.

In an exemplary embodiment, the scan driver may further include a level shifter located between the stages and the buffer unit, the level shifter changing a voltage level of the sampling signal and supplying the changed voltage level to the buffer unit.

In an exemplary embodiment, the ith buffer may include a first transistor coupled between a gate-on voltage source and the output terminal of the ith buffer, the first transistor being turned on when the sampling signal is supplied to the input terminal of the ith buffer, and a second transistor coupled between a gate-off voltage source and the output terminal of the ith buffer, the second transistor being turned on when the sampling signal is not supplied to the input terminal of the ith buffer.

In an exemplary embodiment, the ith buffer and the specific buffer may output a high level of the same clock signal as the sampling signal.

According to an exemplary embodiment of the invention, there is provided a method of driving a scan driver, the method including outputting an ith (i is a natural number) sampling signal from a stage located in an ith channel, inputting the sampling signal to a buffer located in the ith channel and at least one specific buffer located in another channel different from the ith channel, and outputting a scan signal to a scan line located in the ith channel from the buffer located in the ith channel and the specific buffer.

In an exemplary embodiment, the ith channel and the another channel may output a high level of the same clock signal as the sampling signal.

In the scan driver and the driving method thereof according to exemplary embodiments of the invention, a scan signal is supplied to a specific channel using a buffer located in the specific channel and at least one buffers located in another channel. That is, in exemplary embodiments of the invention, a scan signal is supplied to a specific channel using buffers located in a plurality of channels, and accordingly, the slew rate may be improved. Also, in exemplary embodiments of the invention, one buffer is provided for each channel, and hence it is possible to minimize the manufacturing cost and mounting area of the scan driver.

### BRIEF DESCRIPTION OF THE DRAWINGS

Exemplary embodiments will now be described more fully hereinafter with reference to the accompanying drawings, in which:

FIG. 1 is a diagram schematically illustrating a display device according to an exemplary embodiment of the invention;

FIGS. 2A and 2B are diagrams schematically illustrating an exemplary embodiment of a scan driver shown in FIG. 1;

FIGS. 3A and 3B are diagrams schematically illustrating another embodiment of the scan driver shown in FIG. 1;

FIG. 4 is a diagram illustrating an exemplary embodiment of an operating process of the scan driver shown in FIGS. 2A and 2B;

FIG. 5 is a diagram illustrating a buffer unit according to an exemplary embodiment of the invention;

FIG. 6 is a diagram illustrating a buffer unit according to another exemplary embodiment of the invention;

FIG. 7 is a diagram illustrating an exemplary embodiment of a buffer shown in FIG. 5;

FIGS. 8A and 8B are diagrams illustrating an operating process of the buffer shown in FIG. 7; and

FIG. 9 is a diagram illustrating a buffer unit according to another exemplary embodiment of the invention.

### DETAILED DESCRIPTION

In the following detailed description, only certain exemplary embodiments of the invention have been shown and described, simply by way of illustration. As those skilled in the art would realize, the described embodiments may be modified in various different ways, all without departing from the spirit or scope of the invention. Accordingly, the drawings and description are to be regarded as illustrative in nature and not restrictive.

In the entire specification, when an element is referred to as being “connected” or “coupled” to another element, it can be directly connected or coupled to the another element or be indirectly connected or coupled to the another element with one or more intervening elements interposed therebetween. Further, some of the elements that are not essential to the complete understanding of the invention are omitted for clarity. Also, like reference numerals refer to like elements throughout.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this invention will be thorough and complete, and will fully convey the scope of the invention to those skilled in the art. Like reference numerals refer to like elements throughout. In the drawing figures, dimensions may be exaggerated for clarity of illustration.

It will be understood that when an element is referred to as being “between” two elements, it can be the only element between the two elements, or one or more intervening elements may also be present. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. In an exemplary embodiment, when the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, when the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the invention, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. In an exemplary embodiment, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

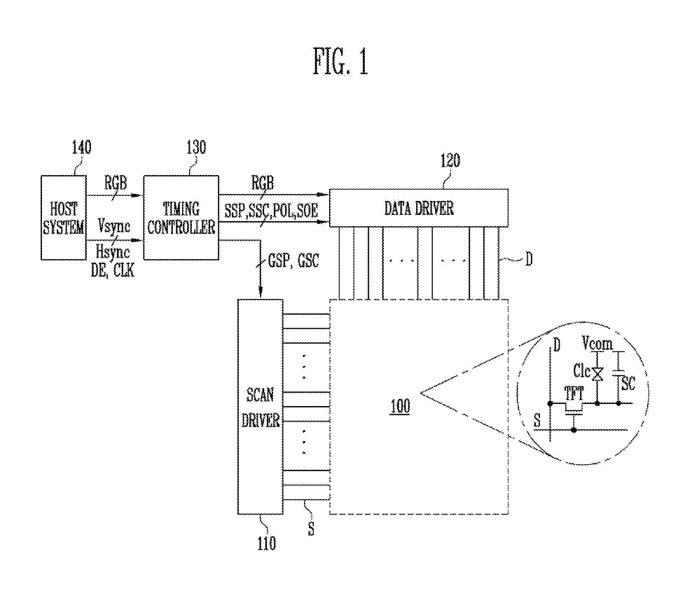

FIG. 1 is a diagram schematically illustrating a display device according to an exemplary embodiment of the invention. In FIG. 1, for convenience of illustration, it is assumed that the display device is a liquid crystal display device, but the invention is not limited thereto.

Referring to FIG. 1, the display device according to the exemplary embodiment of the invention includes a pixel unit 100, a scan driver 110, a data driver 120, a timing controller 130, and a host system 140.

The pixel unit 100 means an effective display unit of a liquid crystal panel. The liquid crystal panel includes a thin film transistor (“TFT”) substrate and a color filter substrate. A liquid crystal layer is disposed between the TFT substrate and the color filter substrate. Data lines D and scan lines S are disposed on the TFT substrate, and a plurality of pixels is arranged in areas defined by the scan lines S and the data lines D.

A TFT included in each pixel transmits, to a liquid crystal capacitor Clc, the voltage of a data signal supplied via a data line D in response to a scan signal from a scan line S. To this end, a gate electrode of the TFT is coupled to the scan line S, and a first electrode of the TFT is coupled to the data line D. Also, a second electrode of the TFT is coupled to the liquid crystal capacitor Clc and a storage capacitor SC.

Here, the first electrode means any one of source and drain electrodes of the TFT, and the second electrode means the other electrode different from the first electrode. When the first electrode is set as the drain electrode, for example, the second electrode is set as the source electrode. The liquid crystal capacitor Clc equivalently represents liquid crystals between a pixel electrode (not shown) and a common electrode, which are disposed on the TFT substrate. The storage capacitor SC maintains the voltage of a data signal transmitted to the pixel electrode for a predetermined time until a next data signal is supplied.

Black matrices, color filters, and the like are disposed on the color filter substrate.

The common electrode is disposed on the color filter substrate in a vertical electric field driving manner such as a twisted nematic (“TN”) mode and a vertical alignment (“VA”) mode, for example. In an exemplary embodiment, the common electrode is provided together with the pixel electrode on the TFT substrate in a horizontal electric field driving manner such as an in-plane switching (“IPS”) mode and a fringe field switching (“FFS”) mode. A common voltage Vcom is supplied to the common electrode, for example. However, the invention is not limited thereto, and the liquid crystal mode of the liquid crystal panel may be implemented in any liquid crystal mode as well as the TN, VA, IPS, and FFS modes.

The data driver 120 converts image data RGB input from the timing controller 130 into a positive/negative gamma compensation voltage to generate a positive/negative analog data voltage. The positive/negative analog data voltage generated by the data driver 120 is supplied as a data signal to the data lines D.

The scan driver 110 supplies a scan signal to the scan lines S. In an exemplary embodiment, the scan driver 110 may sequentially supply the scan signal to the scan lines S, for example. When the scan signal is sequentially supplied to the scan lines S, pixels are selected in units of horizontal lines, and the pixels selected by the scan signal are supplied with a data signal. In an exemplary embodiment, the scan driver 110 may be mounted in an amorphous silicon gate driver (“ASG”) on the liquid crystal panel, for example. That is, the scan driver 110 may be mounted on the TFT substrate through a thin film process. In an exemplary embodiment, the scan driver 110 may be mounted at both sides of the liquid crystal panel with the pixel unit 100 interposed therebetween, for example.

The timing controller 130 supplies a gate control signal to the scan driver 110 and supplies a data control signal to the data driver 120, based on timing signals such as image data RGB, a vertical synchronization signal Vsnyn, a horizontal synchronization signal Hsync, a data enable signal DE, and a clock signal CLK, which are output from the host system 140.

The gate control signal includes a gate start pulse GSP, at least one gate shift clock GSC, and the like. The gate start pulse GSP controls timing of a first scan signal. The gate shift clock GSC means at least one clock signal for shifting the gate start pulse GSP.

The data control signal includes a source start pulse SSP, a source sampling clock SSC, a source output enable signal SOE, a polarity control signal POL, and the like. The source start pulse SSP controls a data sampling start time of the data driver 120. The source sampling clock SSC controls a sampling operation of the data driver 120, based on a rising or falling edge. The source output enable signal SOE controls output timing of the data driver 120. The polarity control signal POL inverts the polarity of a data signal output from the data driver 120 for every cycle of j (j is a natural number) horizontal periods.

The host system 140 supplies image data RGB to the timing controller 130 through an interface such as a low voltage differential signaling (“LVDS”) interface or a transition minimized differential signaling (“TMDS”) interface. Also, the host system 140 supplies timing signals Vsync, Hsync, DE, and CLK to the timing controller 130.

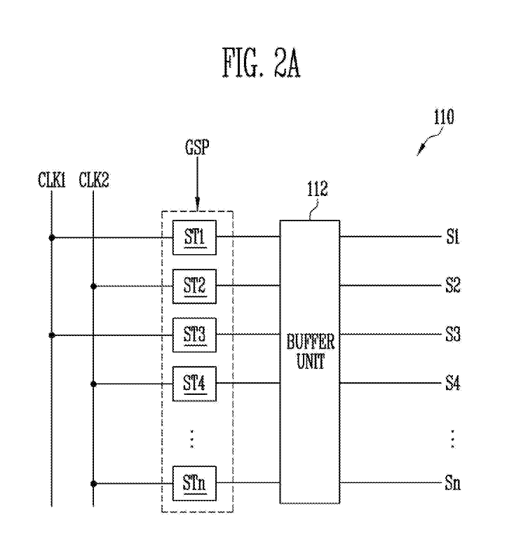

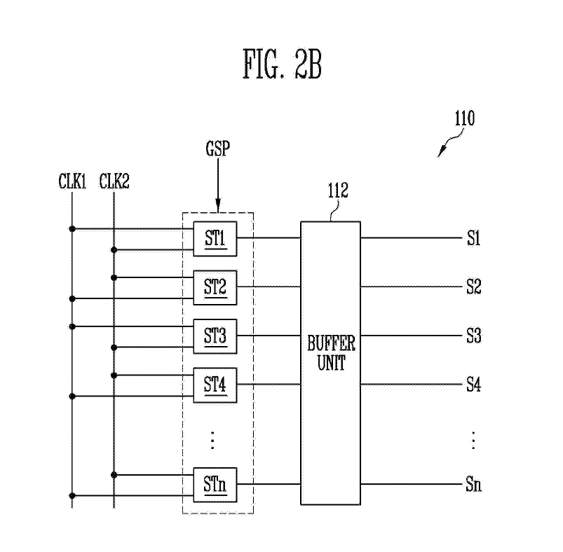

FIG. 2A is a diagram schematically illustrating an exemplary embodiment of the scan driver shown in FIG. 1.

Referring to FIG. 2A, the scan driver 110 according to the exemplary embodiment of the invention includes a plurality of stages ST1 to STn located for every channel and a buffer unit 112 coupled to the stages ST1 to STn.

Each of the stages ST1 to STn supplies a sampling signal to any one of scan lines S1 to Sn, corresponding to a gate start pulse GSP. Here, a stage STi located in an ith row (i is a natural number) may supply the sampling signal to an ith scan line Si.

Each of the stages ST1 to STn receives, as a gate shift clock GSC (refer to FIG. 1), any one of clock signals CLK1 and CLK2 supplied from the timing controller 130. In an exemplary embodiment, odd-numbered stages ST1, ST3, . . . may be driven by a first clock signal CLK1, and even-numbered stages ST2, ST4, . . . may be driven by a second clock signal CLK2, for example.

Additionally, each of the stages ST1 to STn, as shown in FIG. 2B, may be driven by the first clock signal CLK1 and the second clock signal CLK2. That is, in the exemplary embodiment of the invention, each of the stages ST1 to STn may be driven corresponding to at least one clock signal. To this end, each of the stages ST1 to STn may be implemented with various circuits currently known in the art.

The buffer unit 112 supplies a scan signal to the scan lines S1 to Sn, corresponding to the sampling signal supplied from the stages ST1 to STn. In an exemplary embodiment, the buffer unit 112 may supply the scan signal to the ith scan line Si, corresponding to the sampling signal from the stage STi located in the ith channel, for example. That is, the buffer unit 112 outputs, to the ith scan line Si, the scan signal set to a gate-on voltage, when the sampling signal is supplied from the ith stage STi, and supplies a gate-off voltage to the ith scan line Si when the sampling signal is not supplied from the ith stage STi.

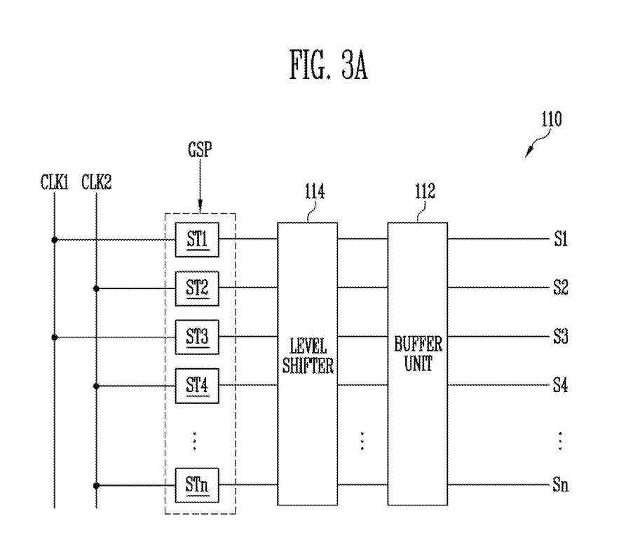

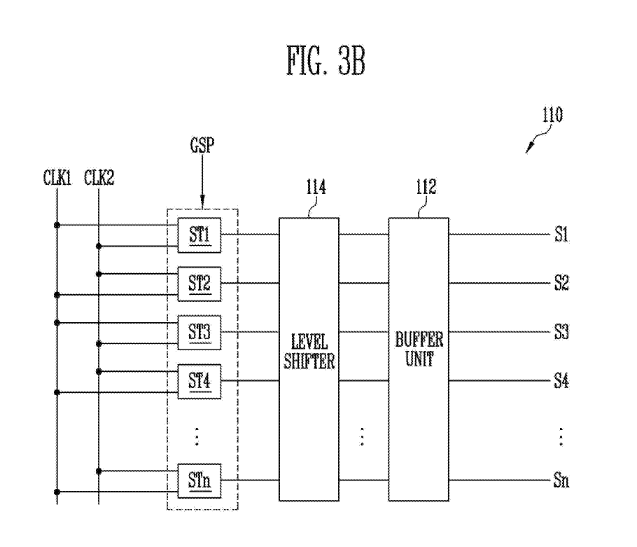

In an exemplary embodiment, as shown in FIGS. 3A and 3B, a level shifter 114 may be additionally provided between the buffer unit 112 and the stages ST1 to STn. The level shifter 114 changes a voltage of the sampling signal and the changed voltage to the buffer unit 112. In an exemplary embodiment, the level shifter 114 may change the voltage of the sampling signal such that transistors are stably turned on and turned off corresponding to the sampling signal, for example.

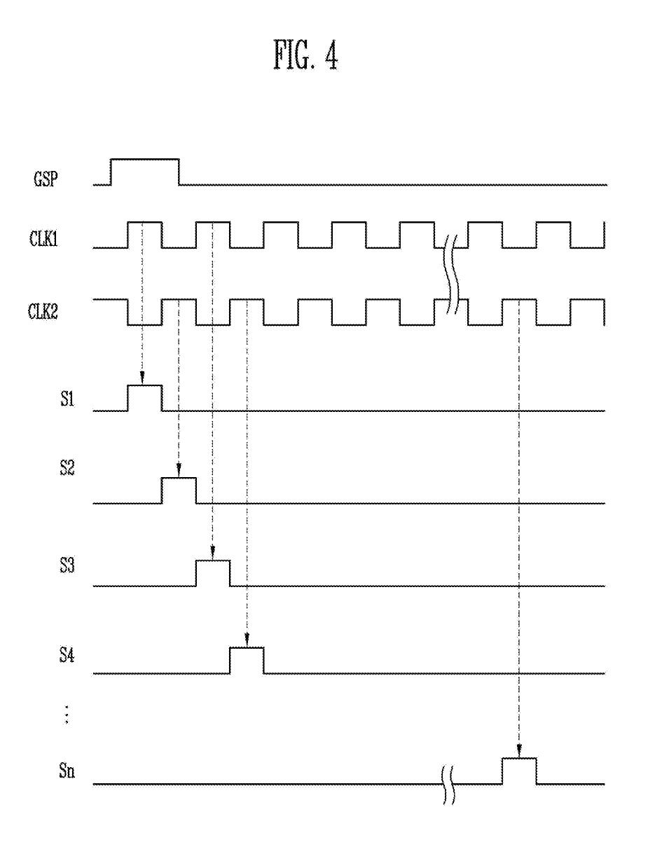

FIG. 4 is a diagram illustrating an exemplary embodiment of an operating process of the scan driver shown in FIGS. 2A and 2B.

Referring to FIG. 4, each of the first clock signal CLK1 and the second clock signal CLK2 are set as a square wave signal in which a high level and a low level are repeated. Here, the second clock signal CLK2 is set to have an inverted phase with respect to the first clock signal CLK1.

The stages ST1 to STn sequentially output a sampling signal, corresponding to the first clock signal CLK1 and/or the second clock signal CLK2. The buffer unit 112 (refer to FIGS. 2A to 3B) sequentially output a scan signal to the scan lines S1 to Sn, corresponding to the sequentially supplied sampling signals.

In an exemplary embodiment, the odd-numbered stages ST1, ST3, . . . may sequentially output a high level of the first clock signal CLK1 as the sampling signal, for example. Also, the even-numbered stages ST2, ST4, . . . may sequentially output a high level of the second clock signal CLK2 as the sampling signal. When the sampling signal is sequentially output from the stages ST1 to STn, the scan signal is sequentially supplied to the scan lines S1 to Sn by the buffer unit 112.

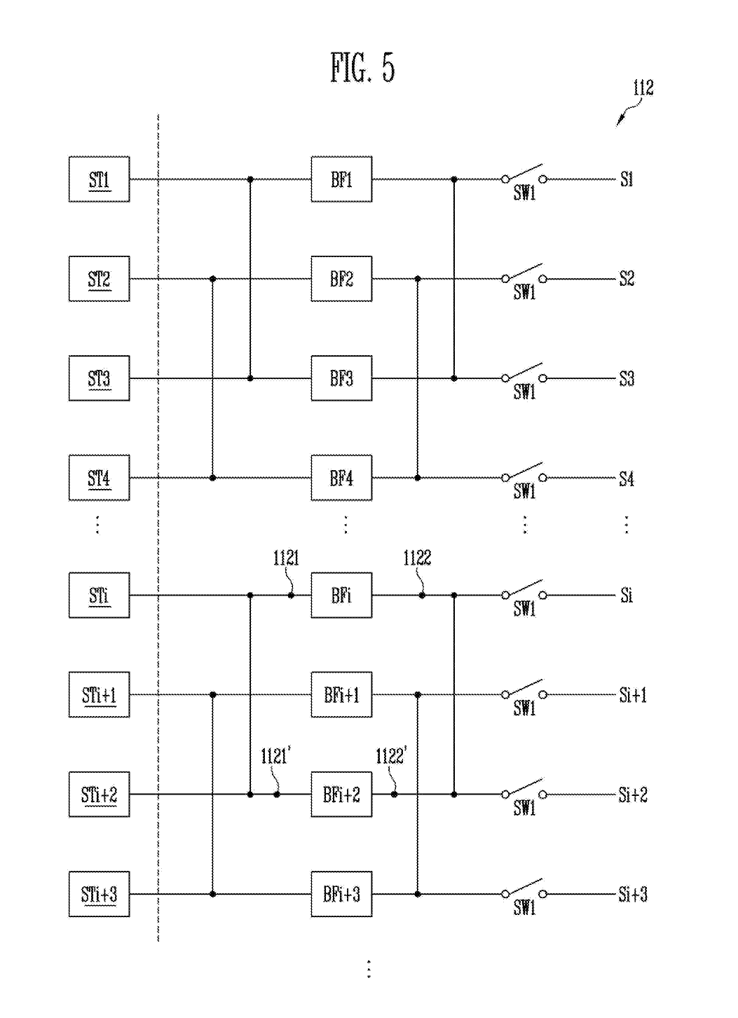

FIG. 5 is a diagram illustrating a buffer unit according to an exemplary embodiment of the invention.

Referring to FIG. 5, the buffer unit 112 according to the exemplary embodiment of the invention includes buffers BF1 to BFn (not shown) coupled between the stages ST1 to STn (refer to FIGS. 2A to 3B) and the scan lines S1 to Sn (refer to FIGS. 2A to 3B), and first switches SW1 respectively coupled between the buffers BF1 to BFn and the scan lines S1 to Sn.

A buffer BFi located in an ith (i is a natural number of n or less) channel may be electrically coupled to at least one specific buffer located in another channel different from the ith channel, e.g., an (i+2)th buffer BFi+2. In other words, an input terminal 1121 of the ith buffer BFi is electrically coupled to an input terminal 1121′ of the (i+2)th buffer BFi+2, and an output terminal 1122 of the ith buffer BFi is electrically coupled to an output terminal 1122′ of the (i+2)th buffer BFi+2.

In this case, when the sampling signal is supplied from the ith stage STi, the scan signal is supplied to the ith scan line Si by the ith buffer BFi and the (i+2)th buffer BFi+2, and accordingly, the slew rate may be improved. Similarly, when the sampling signal is supplied from an (i+2)th stage STi+2, the scan signal is supplied to an (i+2)th scan line Si+2 by the (i+2)th buffer BFi+2 and the ith buffer BFi, and accordingly, the slew rate may be improved.

That is, in the exemplary embodiment of the invention, one buffer is provided for each channel, and the scan signal is supplied to a specific channel using a buffer located in the specific channel and at least one buffers located in another channel. In other words, in the exemplary embodiment of the invention, a scan signal is output using a plurality of buffers, and accordingly, the slew rate of the scan signal may be improved. In the exemplary embodiment of the invention, one buffer is provided for each channel, and hence it is possible to minimize the manufacturing cost and mounting area of the scan driver 110.

In the exemplary embodiment of the invention, channels sharing a buffer may be set as channels that output a high level of the same clock signal as a sampling signal. In an exemplary embodiment, a specific channel and at least one different channel, which share a buffer, output a high level of the first clock signal CLK1 or the second clock signal CLK2 as the sampling signal, for example. When a buffer is shared by channels that output a high level of the same clock signal as the sampling signal, the reliability of operation may be improved.

The first switches SW1 are turned on or turned off corresponding to a supply order of the scan signal. Here, the first switch SW1 coupled to the ith buffer BFi is turned off when the sampling signal is supplied from the (i+2)th stage STi+2, and otherwise, turned on. In addition, the first switch SW1 coupled to the (i+2)th buffer BFi+2 is turned off when the sampling signal is supplied from the ith stage STi, and otherwise, turned on.

As described above, the first switch SW1 located in a specific channel is turned off when the sampling signal is supplied to at least one different channel sharing the specific channel and a buffer, and otherwise, turned on. Similarly, the first switch SW1 located in another channel sharing a buffer BF is also set to the turn-off state when the sampling signal is supplied to a specific channel. In this case, when the scan signal is supplied to the specific channel, the first switch SW1 located in the specific channel is set to the turn-on state, and the first switch SW1 located in another channel sharing the buffer is set to the turn-off state. Hence, the scan signal may be stably supplied.

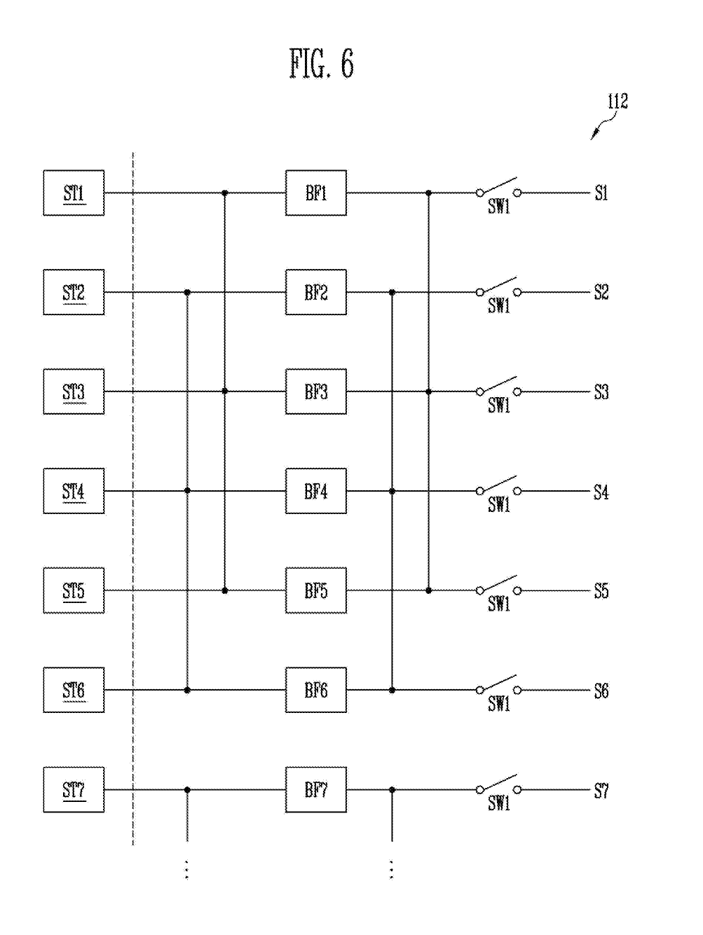

In FIG. 5, it is illustrated that buffers located in two channels are shared, but the invention is not limited thereto. In another exemplary embodiment, as shown in FIG. 6, buffers located in three channels may be shared, for example. That is, in the exemplary embodiment of the invention, buffers located in a plurality of channels are shared, and accordingly, the slew rate of the scan signal may be improved without any increase in a mounting area.

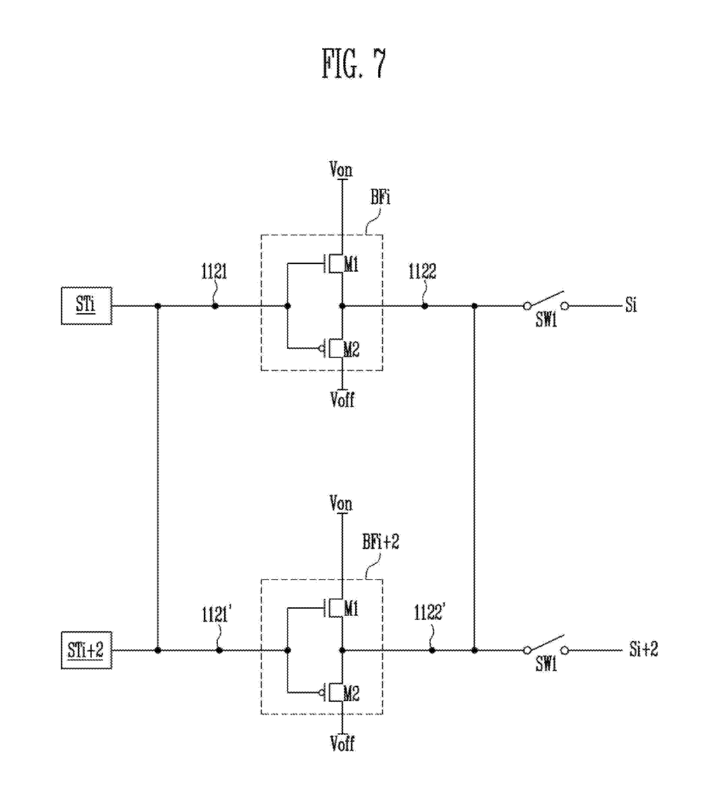

FIG. 7 is a diagram illustrating an exemplary embodiment of the buffer shown in FIG. 5. In FIG. 7, for convenience of illustration, an ith buffer will be mainly described.

Referring to FIG. 7, the ith buffer BFi includes a first transistor M1 coupled between a gate-on voltage source Von and an output terminal 1122 of the ith buffer BFi, and a second transistor M2 coupled between a gate-off voltage source Voff and the output terminal 1122 of the ith buffer BFi. In addition, gate electrodes of the first transistor M1 and the second transistor M2 are coupled to an input terminal 1121 of the ith buffer BFi.

The first transistor M1 and the second transistor M2 supply the gate-on voltage or the gate-off voltage to the output terminal 1122 while being alternately turned on and turned off corresponding to a voltage of the input terminal 1121. To this end, the first transistor M1 and the second transistor M2 are set to different conductive types. In an exemplary embodiment, the first transistor M1 may be provided as an NMOS transistor and the second transistor M2 may be provided as a PMOS transistor, for example.

Additionally, the gate-on voltage means a voltage at which the transistors included in the pixels are turned on, and the gate-off voltage means a voltage at which the transistors included in the pixels are turned off.

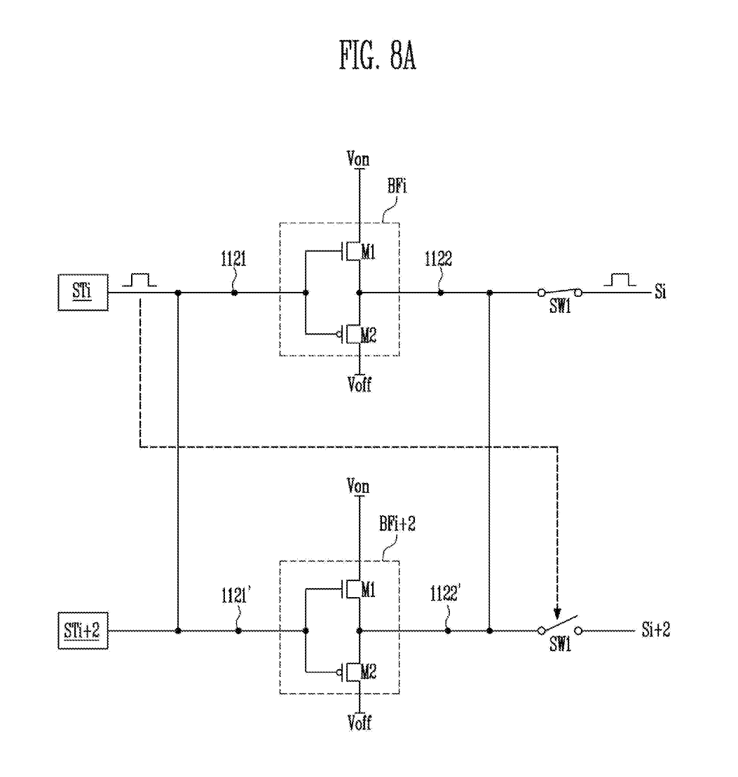

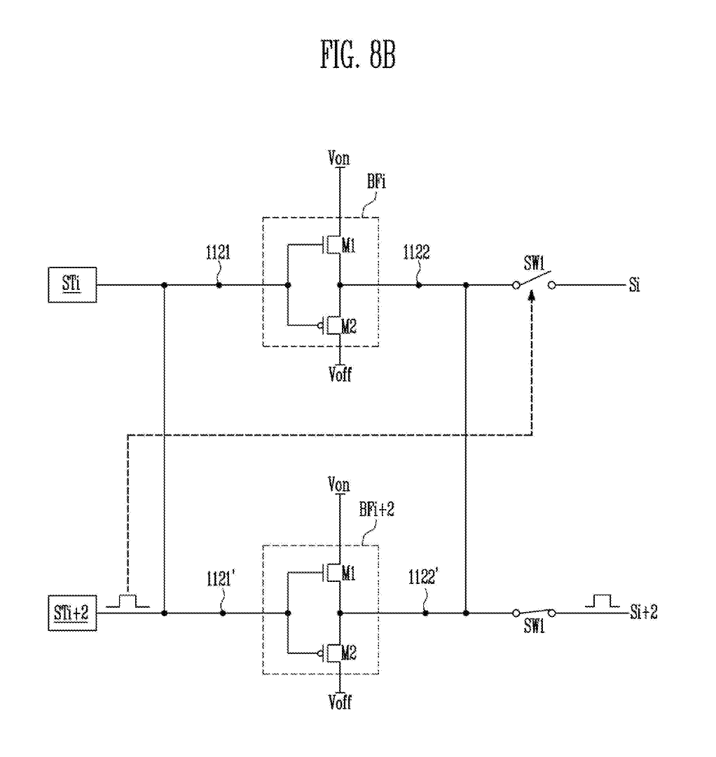

FIGS. 8A and 8B are diagrams illustrating an operating process of the buffer shown in FIG. 7.

Referring to FIG. 8A, first, a sampling signal is output from the ith stage STi. When the sampling signal is supplied from the ith stage STi, the first switch SW1 located in the (i+2)th channel is turned off.

The sampling signal supplied from the ith stage STi is supplied to the input terminal 1121 of the ith buffer BFi and the input terminal 1121′ of the (i+2)th buffer BFi+2. Then, the first transistors M1 included in the ith buffer BFi and the (i+2)th buffer BFi+2 are turned on. When the first transistor M1 is turned on, the gate-on voltage is supplied to the ith scan line Si via the first switch SW1 located in the ith channel. That is, the scan signal supplied to the ith scan line Si is generated by the plurality of buffers BFi and BFi+2, and accordingly, the slew rate may be improved.

Referring to FIG. 8B, when a sampling signal is supplied from the (i+2)th stage STi+2, the first switch SW1 located in the ith channel is turned off. The sampling signal from the (i+2)th stage STi+2 is supplied to the input terminal 1121 of the ith buffer BFi and the input terminal 1121′ of the (i+2)th buffer BFi+2. Then, the first transistors M1 included in the ith buffer BFi and the (i+2)th buffer BFi+2 are turned on. When the first transistor M1 is turned on, the gate-on voltage is supplied to the (i+2)th scan line Si+2 via the first switch SW1 located in the (i+2)th channel. That is, the scan signal supplied to the (i+2)th scan line Si+2 is generated by the plurality of buffers BFi and BFi+2, and accordingly, the slew rate may be improved.

The second transistors M2 included in the ith buffer BFi and the (i+2)th buffer BFi+2 are turned on during a period in which the sampling signal is not supplied from the ith stage STi and the (i+2)th stage STi+2. When the second transistor M2 is turned on, the gate-off voltage is supplied to the ith scan line Si and the (i+2)th scan line Si+2. That is, the gate-off voltage Voff voltage is supplied to the ith scan line Si and the (i+2)th scan line Si+2 during a period in which the scan signal is not supplied.

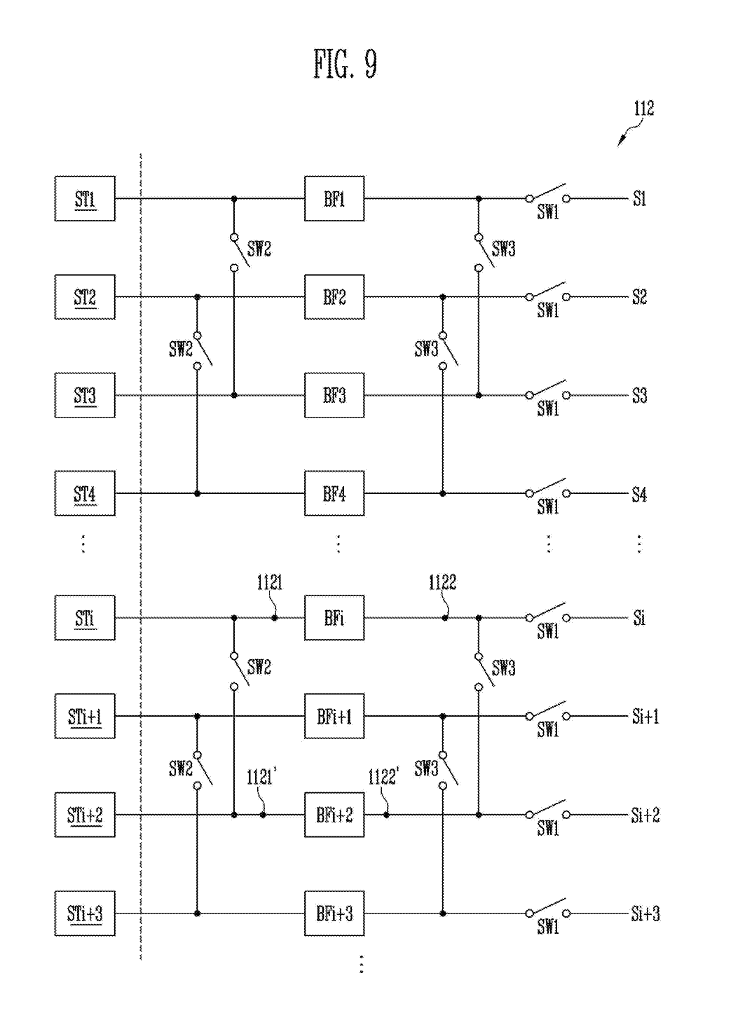

FIG. 9 is a diagram illustrating a buffer unit according to another exemplary embodiment of the invention. In FIG. 9, components identical to those of FIG. 5 are designated by like reference numerals, and their detailed descriptions will be omitted.

Referring to FIG. 9, the buffer unit 112 according to the exemplary embodiment of the invention includes buffers BF1 to BFn (not shown), first switches SW1, second switches SW2, and third switches SW3.

The second switches SW2 are coupled between input terminals of buffers BF sharing a channel. In an exemplary embodiment, a specific second switch SW2 is coupled between an input terminal 1121 of an ith buffer BFi and an input terminal 1121′ of an (i+2)th buffer BFi+2, for example. The specific second switch SW2 may be turned on or turned off corresponding to whether the channel is shared. In an exemplary embodiment, when the specific second switch SW2 is turned on, the buffers BFi and BFi+2 respectively located in an ith channel and an (i+2)th channel are shared, for example. When the specific second switch SW2 is turned off, the buffers BFi and BFi+2 located in the ith channel and the (i+2)th channel are not shared.

The third switches SW3 are coupled between output terminals of buffers BF sharing a channel. In an exemplary embodiment, a specific third switch SW3 is coupled between an output terminal 1122 of the ith buffer BFi and an output terminal 1122′ of the (i+2)th buffer BFi+2, for example. The specific third switch SW3 may be turned on or turned off corresponding to whether the channel is shared. In an exemplary embodiment, when the specific third switch SW3 is turned on, the buffers BFi and BFi+2 located in the ith channel and the (i+2)th channel are shared, for example. When the specific third switch SW3 is turned off, the buffers BFi and BFi+2 located in the ith channel and the (i+2)th channel are not shared. To this end, the specific second switch SW2 and the specific switch SW3 may be simultaneously turned on or turned off.

As described above, according to the exemplary embodiment of the invention shown in FIG. 9, the added second and third switches SW2 and SW3 are used to control whether a channel is shared. That is, the second and third switches SW2 and SW3 enable a designer to determine whether the channel is share. The second and third switches SW2 and SW3 may be used in a developing process, etc.

Exemplary embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other exemplary embodiments unless otherwise specifically indicated. Accordingly, it will be understood by those of skill in the art that various changes in form and details may be made without departing from the spirit and scope of the disclosure as set forth in the following claims.

What is claimed is:

1. A scan driver comprising:
stages which are respectively located in channels, and respectively output sampling signals, corresponding to at least one clock signal; and
a buffer unit including buffers which are respectively located between the stages and scan lines, and respectively output scan signals to output terminals thereof, corresponding to the sampling signals respectively supplied through input terminals thereof,
wherein an ith (i is a natural number) buffer of the buffer unit located in an ith channel is electrically coupled to at least one specific buffer located in another channel different from the ith channel.

2. The scan driver of claim 1, wherein an input terminal of the ith buffer is electrically coupled to an input terminal of the at least one specific buffer, and an output terminal of the ith buffer is electrically coupled to an output terminal of the specific buffer.

3. The scan driver of claim 2, further comprising first switches respectively coupled between the buffers and the scan lines.

4. The scan driver of claim 3, wherein a first switch coupled to the ith buffer is turned off when the sampling signal is supplied to the specific buffer, and otherwise, set to a turn-on state.

5. The scan driver of claim 2, further comprising:
a second switch coupled between the input terminal of the ith buffer and the input terminal of the specific buffer; and
a third switch coupled between the output terminal of the ith buffer and the output terminal of the specific buffer.

6. The scan driver of claim 1, further comprising a level shifter which is located between the stages and the buffer unit, changes a voltage level of the sampling signal and supplies the changed voltage level to the buffer unit.

7. The scan driver of claim 1, wherein the ith buffer includes:
a first transistor which is coupled between a gate-on voltage source and the output terminal of the ith buffer, and is turned on when the sampling signal is supplied to the input terminal of the ith buffer; and
a second transistor which is coupled between a gate-off voltage source and the output terminal of the ith buffer, and is turned on when the sampling signal is not supplied to the input terminal of the ith buffer.

8. The scan driver of claim 1, wherein the ith buffer and the at least one specific buffer output a high level of the same clock signal as the sampling signal.

9. A method of driving a scan driver, the method comprising:
outputting an ith (i is a natural number) sampling signal from a stage located in an ith channel;
inputting the sampling signal to a buffer located in the ith channel and at least one specific buffer located in another channel different from the ith channel; and
outputting a scan signal to a scan line located in the ith channel from the buffer located in the ith channel and the at least one specific buffer.

10. The method of claim 9, wherein the ith channel and the another channel output a high level of the same clock signal as the sampling signal.
